(19) United States
(12) Patent Application Publication
(10) Pub. No.: US 2026/0033374 A1
(43) Pub. Date: Jan. 29, 2026

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: Chien-Chang Lin, New Taipei City (TW); Yen-Fu Su, Hsinchu City (TW); Chih-Kai Cheng, Hsinchu County (TW); Chien-Chia Chiu, Taoyuan City (TW); Hua-Wei Tseng, New Taipei City (TW)

(73) Assignee: Taiwan Semiconductor Manufacturing Company, Ltd., Hsinchu (TW)

(21) Appl. No.: 18/784,939

(22) Filed: Jul. 26, 2024

(51) Int. Cl. H01L 23/00; H01L 25/065

(52) U.S. Cl. CPC H01L 24/13; H01L 24/03; H01L 24/05; H01L 24/11; H01L 24/16; H01L 24/32; H01L 24/73; H01L 25/0657; H01L 2224/0347; H01L 2224/0401; H01L 2224/05082; H01L 2224/05647; H01L 2224/05655; H01L 2224/1147; H01L 2224/11849; H01L 2224/13018; H01L 2224/13083; H01L 2224/13111; H01L 2224/13147; H01L 2224/13155; H01L 2224/16058; H01L 2224/16145; H01L 2224/16221; H01L 2224/32145; H01L 2224/73204; H01L 2225/06513

(57) ABSTRACT

Provided are a semiconductor structure and a method of forming the same. The semiconductor structure includes: a substrate, an under bump metallurgy (UBM) structure, and a solder. The UBM structure is disposed over the substrate. The UBM structure includes a first metal layer; a second metal layer disposed on the first metal layer; and a third metal layer disposed on the second metal layer. A sidewall of the first metal layer is substantially aligned with a sidewall of the second metal layer, and a sidewall of the third metal layer is laterally offset inwardly from the sidewalls of the first and second metal layers. The solder is disposed on the third metal layer.

### BACKGROUND

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

Although existing package structures and methods of fabricating package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1G are cross-sectional views of a method of forming a semiconductor structure with an under bump metallurgy (UBM) structure in accordance with some embodiments.

FIG. 2 is a cross-sectional view of a semiconductor structure with a connector in accordance with some embodiments.

FIG. 3A is a cross-sectional view of a semiconductor structure with an UBM structure in accordance with some embodiments.

FIG. 3B is a top view of the UBM structure of FIG. 3A.

FIG. 4A is a cross-sectional view of a semiconductor structure with an UBM structure in accordance with some alternative embodiments.

FIG. 4B and FIG. 4C are top views of the UBM structure of FIG. 4A in accordance with various embodiments.

FIG. 5A is a cross-sectional view of a semiconductor structure with an UBM structure in accordance with some other embodiments.

FIG. 5B and FIG. 5C are top views of the UBM structure of FIG. 5A in accordance with various embodiments.

FIG. 6 through FIG. 9 are cross-sectional views of a package structure with a plurality of connectors in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

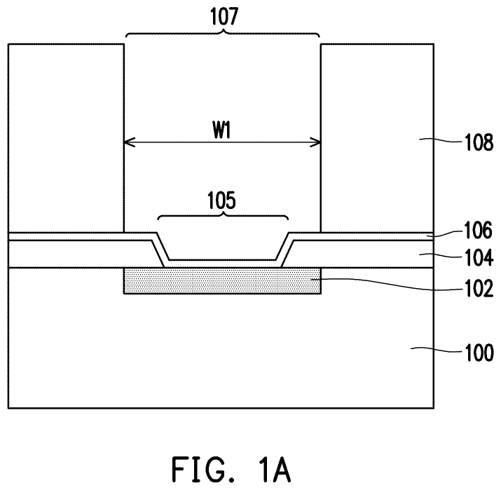

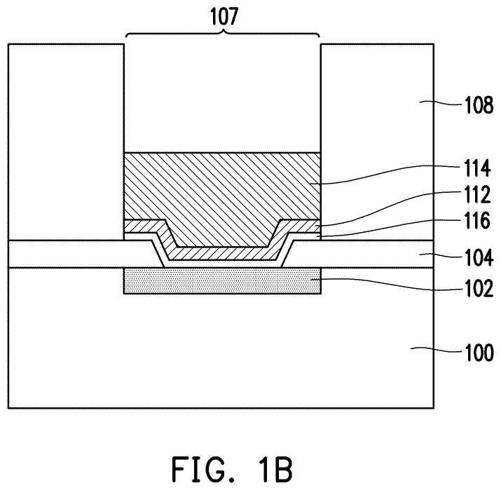

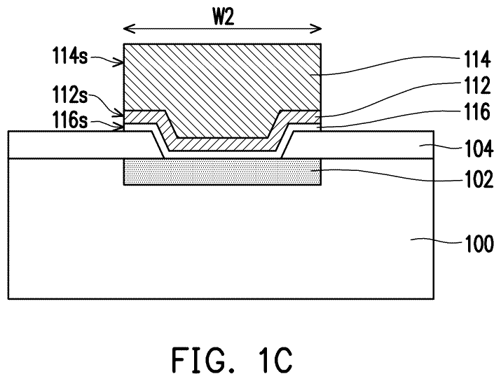

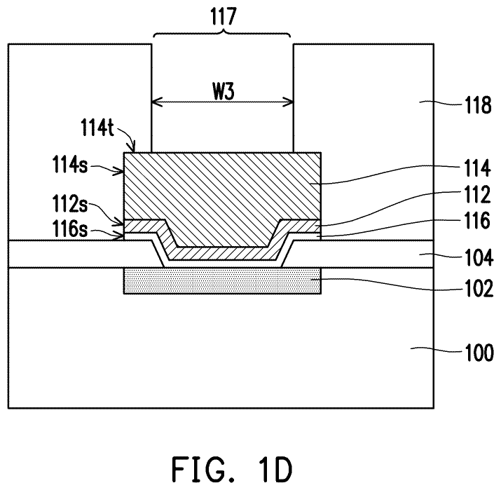

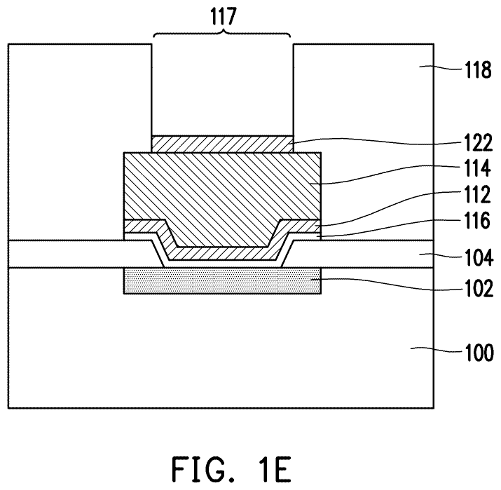

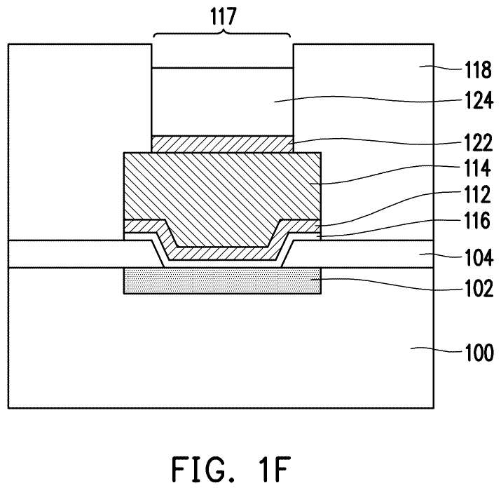

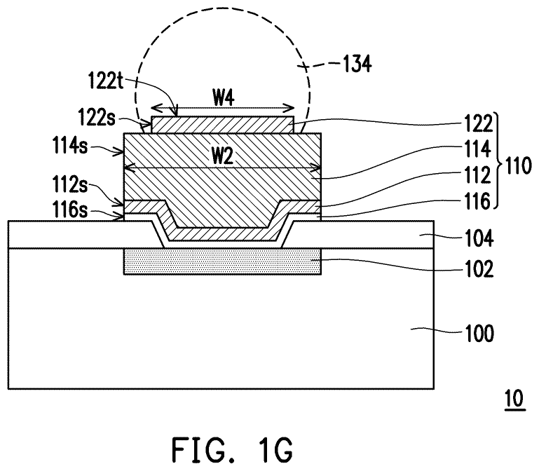

FIG. 1A to FIG. 1G are cross-sectional views of a method of forming a semiconductor structure with an under bump metallurgy (UBM) structure in accordance with some embodiments.

Referring to FIG. 1A, a substrate 100 is provided. In some embodiments, the substrate 100 may be made of silicon or other semiconductor materials. For example, the substrate 100 may be a silicon substrate. Alternatively, or additionally, the substrate 100 may include other elementary semiconductor materials such as germanium. In some embodiments, the substrate 100 is made of a compound semiconductor such as silicon carbide, gallium arsenic, indium arsenide or indium phosphide. In some embodiments, the substrate 100 is made of an alloy semiconductor such as silicon germanium, silicon germanium carbide, gallium arsenic phosphide, or gallium indium phosphide. Furthermore, the substrate 100 may be a semiconductor on insulator such as silicon on insulator (SOI) or silicon on sapphire.

In some embodiments, the substrate 100 may include a device region. The device region includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the device region includes a gate structure, source/drain regions, and isolation structures, such as shallow trench isolation (STI) structures (not shown). In the device region, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed in or on the substrate 100. The functions of the devices may include memory, processors, sensors, amplifiers, power distribution, input/output circuitry, or the like.

In some embodiments, the substrate 100 may include an interconnect structure formed over the device layer. Specifically, the interconnect structure includes an insulating material and a plurality of metal features. The metal features are formed in the insulating material and electrically connected with each other. In some embodiments, the insulating material includes an inner-layer dielectric (ILD) layer, and at least one inter-metal dielectric (IMD) layer over the inner-layer dielectric layer. In some embodiments, the insulating material includes silicon oxide, silicon oxynitride, silicon nitride, low dielectric constant (low-k) materials or a combination thereof. In some alternatively embodiments, the insulating material may be a single layer or multiple layers. In some embodiments, the metal features include plugs and metal lines. The plugs may include contacts formed in the inner-layer dielectric layer, and vias formed in the inter-metal dielectric layer. The contacts are formed between and in connect with the device layer and a bottom metal line. The vias are formed between and in connect with two metal lines. The metal features may be made of tungsten (W), copper (Cu), copper alloys, aluminum (Al), aluminum alloys, or a combination thereof. In some alternatively embodiments, a barrier layer may be formed between the metal features and the insulating material to prevent the material of the metal features from migrating to the device region. A material of the barrier layer includes tantalum, tantalum nitride, titanium, titanium nitride, cobalt-tungsten (CoW) or a combination thereof, for example.

As shown in FIG. 1A, a conductive pad 102 may be formed in the substrate 100. In some embodiments, the conductive pad 102 is a metallization layer formed over the ILD layer of the interconnect structure. The conductive pad 102 may be a top metal feature of the interconnect structure which is a portion of conductive routes and has an exposed surface treated by a planarization process, such as chemical mechanical polishing (CMP), if necessary. In some embodiments, the conductive pad 102 includes a metal material, such as copper, aluminum, copper alloy, or other suitable metal material, although it may also be formed of, or include, other materials such as copper, silver, gold, nickel, tungsten, alloys thereof, and/or multi-layers thereof. In one embodiment, the conductive pad 102 is a pad region, a terminal region or a portion of a conductive line in the interconnect structure, which may be used to connect the integrated circuits of the device region in the substrate 100 to external components.

A passivation layer 104 may be formed on the substrate 100. Specifically, the passivation layer 104 may be formed on the substrate 100, overlying the conductive pad 102. Using photolithography and etching processes, the passivation layer 104 is patterned to form an opening 105 exposing a middle portion of the conductive pad 102. In some embodiments, the passivation layer 104 is formed of a non-organic material selected from un-doped silicate glass (USG), silicon nitride, silicon oxynitride, silicon oxide, and combinations thereof. In some alternative embodiments, the passivation layer 104 is formed of a polymer layer, such as an epoxy, polyimide, benzocyclobutene (BCB), polybenzoxazole (PBO), and the like, although other relatively soft, often organic, dielectric materials can also be used.

FIG. 1A also depicts the formation of a bottom metal material 106. The bottom metal material 106 may be formed on the passivation layer 104, extend to cover the opening 105, and be electrically connected to the conductive pad 102. In an embodiment, the bottom metal material 106 includes a diffusion barrier layer and/or a seed layer. The diffusion barrier layer, also referred to as a glue layer, is formed to cover the sidewalls and the bottom of the opening 105 in the passivation layer 104. The diffusion barrier layer may be formed of titanium, although it may also be formed of other materials such as titanium nitride, tantalum, tantalum nitride, or the like. The formation methods include physical vapor deposition (PVD) or sputtering. The seed layer may be a copper seed layer formed on the diffusion barrier layer using PVD or sputtering. The seed layer may be formed of copper alloys that include silver, chromium, nickel, tin, gold, or combinations thereof. In one embodiment, the bottom metal material 106 includes a Ti layer and a Cu seed layer.

FIG. 1A further depicts the formation a first mask layer 108. The first mask layer 108 may be patterned with a first opening 107 for example, by exposure, development or etching, so that a portion of the bottom metal material 106 is exposed. The first opening 107 may correspond to the underlying opening 105. That is, the first opening 107 may be directly over the opening 105. In some embodiments, the first mask layer 108 includes a dry film or a photoresist film, and the first opening 107 has a width W1 in a horizontal direction.

Referring to FIG. 1B, a first metal layer 112 and a second metal layer 114 are sequentially formed in the first opening 107. In some embodiments, the first metal layer 112 and the second metal layer 114 have different metal materials. For example, the first metal layer 112 is a copper (Cu) layer, and the second metal layer 114 is a nickel (Ni) layer. However, the embodiments of the present invention are not limited thereto. In some alternative embodiments, the first metal layer 112 may be a copper-containing layer such as a copper alloy layer, and the second metal layer 114 may be a nickel-containing layer such as a nickel alloy layer, for example nickel-palladium-gold (NiPdAu), nickel-gold (NiAu), nickel-palladium (NiPd) or other similar alloys. In some embodiments, the first metal layer 112 and the second metal layer 114 are independently formed by a deposition process, such as an electroplating process, an electroless process, an immersion process, a PVD process, a CVD process, or another applicable process. The thickness of the second metal layer 114 illustrated in FIG. 1B is greater than that of the first metal layer 112, however, the embodiments of the present invention are not limited thereto. In some alternative embodiments, the thickness of the first metal layer 112 and/or the second metal layer 114 can be adjusted according to the needs.

Referring to FIG. 1B and FIG. 1C, after removing the first mask layer 108, a first etching process is performed to remove the bottom metal material 106 uncovered by the first metal layer 112 and the second metal layer 114, thereby forming a bottom metal layer 116. In some embodiments, the first etching process is used to remove the bottom metal material 106, but not remove the first metal layer 112 and the second metal layer 114. In other words, the first etching process provides a high etching selectivity of the bottom metal material 106 relative to the first metal layer 112 and the second metal layer 114. That is, the etching rate of the bottom metal material 106 is greater than the etching rate of the first metal layer 112 and the second metal layer 114 during the first etching process.

After removing the first mask layer 108 and the bottom metal material 106 uncovered by the first metal layer 112 and the second metal layer 114, a sidewall 116s of the bottom metal layer 116, a sidewall 112s of the first metal layer 112, and a sidewall 114s of the second metal layer 114 are exposed. In some embodiments, the sidewall 116s of the bottom metal layer 116, the sidewall 112s of the first metal layer 112, and the sidewall 114s of the second metal layer 114 are vertically aligned with each other to form a plane. From another perspective, the bottom metal material 106, the first metal layer 112, and the second metal layer 114 may have the same width W2 in the horizontal direction which corresponds to the width W1 of the first opening 107 (FIG. 1A).

Referring to FIG. 1D, a second mask layer 118 may be formed over the substrate 100. The second mask layer 118 may be patterned with a second opening 117 for example, by exposure, development or etching, so that a portion of the second metal layer 114 is exposed. In this case, as shown in FIG. 1D, the second mask layer 118 may extend along the sidewall 116s of the bottom metal layer 116, the sidewall 112s of the first metal layer 112, and the sidewall 114s of the second metal layer 114 and further cover a portion of a top surface 114t of the second metal layer 114. In some embodiments, the second mask layer 118 includes a dry film or a photoresist film, and the second opening 117 has a width W3 in the horizontal direction less than the width W1 of the first opening 107 (FIG. 1A).

Referring to FIG. 1E, a third metal layer 122 may be formed in the second opening 117 and on the second metal layer 114. In some embodiments, the third metal layer 122 and the second metal layer 114 have different metal materials. For example, the third metal layer 122 is a copper (Cu) layer, and the second metal layer 114 is a nickel (Ni) layer. However, the embodiments of the present invention are not limited thereto. In some embodiments, the third metal layer 122 may be a copper-containing layer such as a copper alloy layer, and may be formed by a deposition process, such as an electroplating process, an electroless process, an immersion process, a PVD process, a CVD process, or another applicable process. In the present embodiment, the first metal layer 112 and the third metal layer 122 have the same material, and a material of the second metal layer 114 is different from a material of the first metal layer 112 and the third metal layer 122. For example, the material of the first and third metal layers 112 and 122 is a copper-containing material, and the material of the second metal layer 114 is a nickel-containing material.

Referring to FIG. 1F, a solder 124 may be formed in the second opening 117 and on the third metal layer 122. In some embodiments, the solder 124 is made of Sn, SnAg, Sn—Pb, SnAgCu, SnAgZn, SnZn, SnBi—In, Sn—In, Sn—Au, SnPb, SnCu, SnZnIn, or SnAgSb, or the like, and may be formed by an electroplating or an immersion process. In one embodiment, the solder 124 is a lead-free solder material layer.

Referring to FIG. 1F and FIG. 1G, after removing the second mask layer 118, the bottom metal layer 116, the first metal layer 112, the second metal layer 114, the third metal layer 122, and the solder 124 are exposed. Specifically, the sidewall 116s of the bottom metal layer 116, the sidewall 112s of the first metal layer 112, the sidewall 114s of the second metal layer 114, and a sidewall 122s of the third metal layer 122 are exposed. In some embodiments, the sidewall 116s of the bottom metal layer 116, the sidewall 112s of the first metal layer 112, and the sidewall 114s of the second metal layer 114 are vertically aligned with each other to form the plane. In addition, the sidewall 122s of the third metal layer 122 may be laterally offset inwardly from the sidewalls 116s/112s/114s of the bottom, first and second metal layers 116/112/114. From another perspective, the third metal layer 122 has a width W4 in the horizontal direction less than the same width W2 of the bottom metal material 106, the first metal layer 112, and the second metal layer 114.

As shown in FIG. 1G, after removing the second mask layer 118, a reflow process may be performed on the solder 124 to form a ball-shaped solder bump 134, thereby accomplishing a semiconductor structure 10 with an UBM structure 110. The UBM structure 110 may include the bottom metal layer 116, the first metal layer 112, the second metal layer 114, and the third metal layer 122 from bottom to top. The solder bump 134 may cover a surface (including a top surface 122t and the sidewall 122s) of the third metal layer 122, but not extend to cover the sidewall 114s of the second metal layer 114.

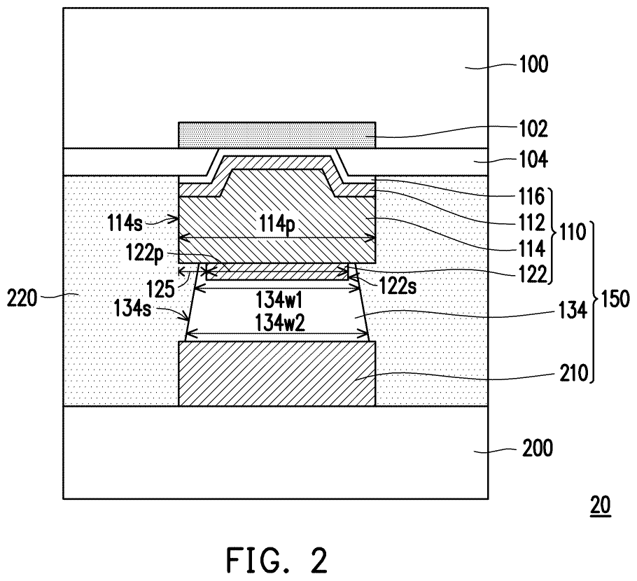

FIG. 2 is a cross-sectional view of a semiconductor structure with a connector in accordance with some embodiments.

Referring to FIG. 2, the structure 10 of FIG. 1G may be flipped upside down and bonded to another substrate 200. In detail, the upper substrate 100 may be bonded to the lower substrate 200 through a connector 150, and an underfill layer 220 may be formed to laterally encapsulate the connector 150. In some embodiments, the connector 150 includes the UBM structure 110 connecting the upper substrate 100, a metal pillar (e.g., copper pillar) 210 connecting the lower substrate 200, and the solder bump 134 sandwiched between the UBM structure 110 and the metal pillar 210. In some embodiments, the underfill layer 220 may be any acceptable material, such as a polymer, epoxy, molding underfill, or the like. It should be noted that, in the present embodiment, the third metal layer 122 has a perimeter 122p within a perimeter 114p of the second metal layer 114. Specifically, the sidewall 122s of the third metal layer 122 is laterally offset inwardly from the sidewall 114s of the second metal layer 114, so that a non-zero distance 125 is included between the sidewall 122s of the third metal layer 122 and the sidewall 114s of the second metal layer 114. In this case, the non-zero distance 125 or the step difference defined by the second metal layer 114 and the third metal layer 122 may accommodate the excess solder bump 134 to avoid the solder bump 134 extending to cover the sidewall 114s of the second metal layer 114. As such, an adhesion between the second metal layer 114 and the underfill layer 220 can be effectively improved and further avoid the delamination issue of the underfill layer 220, thereby enhancing the reliability of a semiconductor structure 20 with the connector 150.

On the other hand, in some embodiments, a first width 134w1 of the solder 134 adjacent to the UBM structure 110 is less than a second width 134w2 of the solder 134 adjacent to the metal pillar 210. Specifically, a profile of the solder bump 134 may extend along an edge of the smaller third metal layer 122 and an edge of the greater metal pillar 210. In this case, the solder bump 134 may have a tapered sidewall 134s extending outward from the edge of the third metal layer 122 to the edge of the metal pillar 210. In some embodiments, the solder bump 134 may cover the sidewall 122s of the third metal layer 122. In some alternative embodiments, the solder bump 134 may not cover the sidewall 122s of the third metal layer 122. Although the sidewall 134s of the solder bump 134 of FIG. 2 is illustrated as a straight sidewall, the embodiments of the present invention are not limited thereto. In other embodiments, the sidewall 134s of the solder bump 134 may be a curved or arc sidewall.

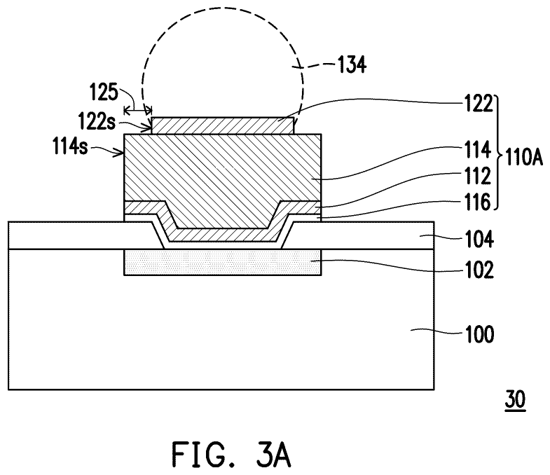

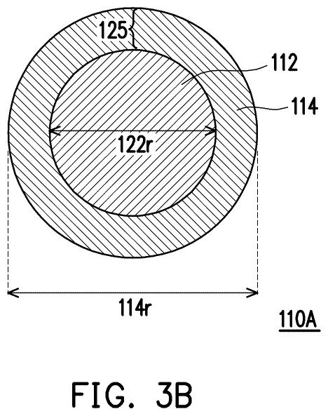

FIG. 3A is a cross-sectional view of a semiconductor structure with an UBM structure in accordance with some embodiments. FIG. 3B is a top view of the UBM structure of FIG. 3A.

Referring to FIG. 3A and FIG. 3B, a semiconductor structure 30 may include an UBM structure 110A over the substrate 100. In some embodiments, the UBM structure 110A includes the bottom metal layer 116, the first metal layer 112, the second metal layer 114, and the third metal layer 122 from bottom to top. The solder bump 134 may be disposed on the third metal layer 122. It should be noted that, in the present embodiment, the sidewall 122s of the third metal layer 122 is laterally offset inwardly from the sidewall 114s of the second metal layer 114, so that the non-zero distance 125 is included between the sidewall 122s of the third metal layer 122 and the sidewall 114s of the second metal layer 114. In this case, the non-zero distance 125 may be referred to as a buffer region to prevent the solder bump 134 from wetting the sidewall 114s of the second metal layer 114, thereby resulting in an intermetallic compound (IMC) on the sidewall 114s of the second metal layer 114. The undesired IMC will cause the poor adhesion between the second metal layer 114 and the subsequently formed underfill layer 220 (FIG. 2) and further result in the delamination issue of the underfill layer 220. As shown in the top view of FIG. 3B, an area of the third metal layer 122 completely overlaps an area of the second metal layer 114. In some embodiments, a ratio of the diameter 122r of the third metal layer 122 to the diameter 114r of the second metal layer 114 is 0.6 to 0.8. The buffer space 125 may be a ring shape laterally surrounding the third metal layer 122 in the top view. In such embodiment, the buffer space or distance 125 can avoid the undesired IMC generation to increase the adhesion between the second metal layer 114 and the underfill layer 220, thereby enhancing the reliability of the semiconductor structure 30 with the UBM structure 110A.

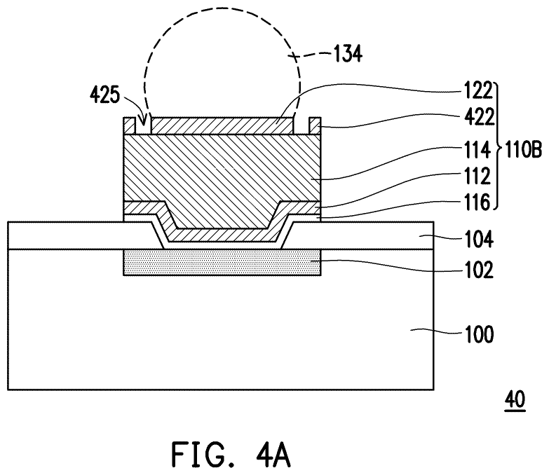

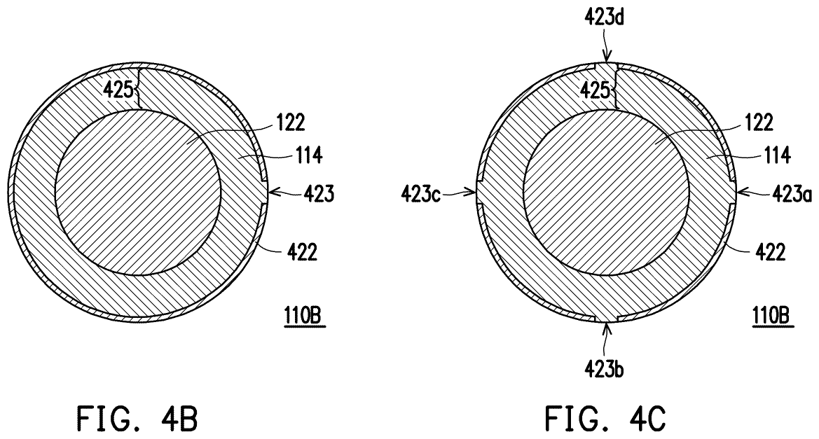

FIG. 4A is a cross-sectional view of a semiconductor structure with an UBM structure in accordance with some alternative embodiments. FIG. 4B and FIG. 4C are top views of the UBM structure of FIG. 4A in accordance with various embodiments.

Referring to FIG. 4A and FIG. 4B, a semiconductor structure 40 with an UBM structure 110B of FIG. 4A is similar to the semiconductor structure 30 with the UBM structure 110A of FIG. 3A, that is, the structures, materials, and functions of the UBM structure 110B are similar to those of the UBM structure 110A, and thus the details are omitted herein. The main difference between the semiconductor structure 40 and the semiconductor structure 30 lies in that the UBM structure 110B further includes a blocking structure 422 on the second metal layer 114. Specifically, as shown in the top view of FIG. 4B and FIG. 4C, the blocking structure 422 may be a ring structure laterally surrounding the third metal layer 122. In some embodiments, the blocking structure 422 and the third metal layer 122 may have the same material such as copper (Cu), and may be at the same level. That is, the blocking structure 422 and the third metal layer 122 may be formed in the same process step. For example, as shown in FIG. 1D and FIG. 1E, the second mask layer 118 further include a ring opening laterally surrounding the second opening 117, and a metal material is formed to fill in the ring opening and the second opening 117 at the same time, thereby forming the blocking structure 422 and the third metal layer 122 in the same deposition step.

It should be noted that, in the present embodiment, a recess 425 is included between the blocking layer 422 and the third metal layer 122. The recess 425 may accommodate the excess solder bump 134 to avoid the solder bump 134 extending to cover the sidewall 114s of the second metal layer 114. In addition, the outside blocking layer 422 may be referred to as a dam structure to block the solder bump 134 wetting on the sidewall 114s of the second metal layer 114. As such, the adhesion between the second metal layer 114 and the subsequently formed underfill layer 220 can be effectively improved and further avoid the delamination issue of the underfill layer 220, thereby enhancing the reliability of the semiconductor structure 40 with the UBM structure 110B. In some embodiments, the blocking structure 422 may be a ring structure with at least one opening 423. The opening 423 can facilitate to remove the excess air when the excess solder bump 134 fills into the recess 425, so as to avoid the undesired void formed in the solder bump 134 in the recess 425. Although the opening 423 of the blocking layer 422 illustrated in FIG. 4B is only one opening, the embodiments of the present invention are not limited thereto. In some alternative embodiments, the blocking layer 422 may include more than one opening, for example four openings 423a, 423b, 423c, 423d, as shown in FIG. 4C. The four openings 423a, 423b, 423c, 423d may be evenly distributed along the perimeter of the blocking layer 422 to remove excess air more efficiently. The number and arrangement of the openings may be adjusted according to needs, and the embodiments of the present invention are not limited thereto.

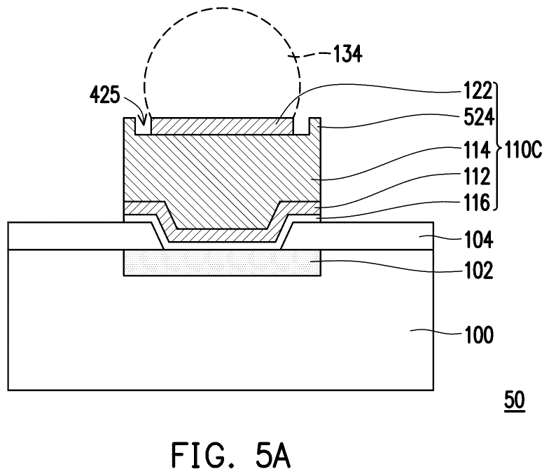

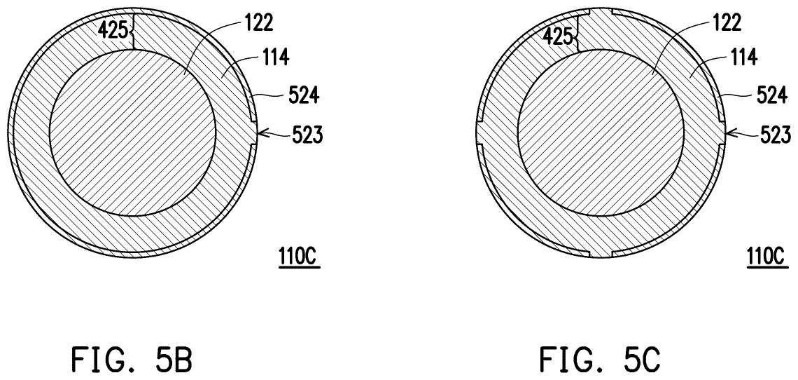

FIG. 5A is a cross-sectional view of a semiconductor structure with an UBM structure in accordance with some other embodiments. FIG. 5B and FIG. 5C are top views of the UBM structure of FIG. 5A in accordance with various embodiments.

Referring to FIG. 5A and FIG. 5B, a semiconductor structure 50 with an UBM structure 110C of FIG. 5A is similar to the semiconductor structure 40 with an UBM structure 110B of FIG. 4A, that is, the structures, materials, and functions of the UBM structure 110C are similar to those of the UBM structure 110B, and thus the details are omitted herein. The main difference between the semiconductor structure 50 and the semiconductor structure 40 lies in that a blocking structure 524 of the UBM structure 110C and the second metal layer 114 have the same material such as nickel (Ni). The outside blocking layer 524 may be referred to as a dam structure to block the solder bump 134 wetting on the sidewall 114s of the second metal layer 114. As such, the adhesion between the second metal layer 114 and the subsequently formed underfill layer 220 can be effectively improved and further avoid the delamination issue of the underfill layer 220, thereby enhancing the reliability of the semiconductor structure 50 with the UBM structure 110C. Further, as shown in FIG. 5B and FIG. 5C, the blocking structure 524 may be a ring structure with one or more openings 523. The openings 523 can facilitate to remove the excess air when the excess solder bump 134 fills into the recess 425, so as to avoid the undesired void formed in the solder bump 134 in the recess 425. The number and arrangement of the openings 523 may be adjusted according to needs, and the embodiments of the present invention are not limited thereto.

The UBM structure discussed in the above embodiments may be applied in various packaging structures with a plurality of connectors, which will be described in detail below.

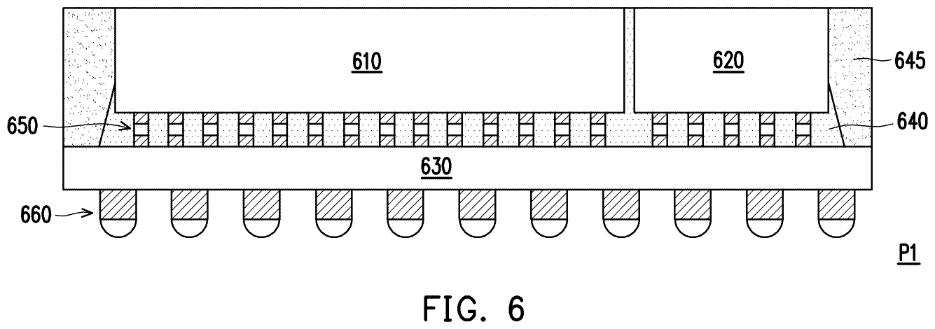

FIG. 6 through FIG. 9 are cross-sectional views of a package structure with a plurality of connectors in accordance with various embodiments.

Referring to FIG. 6, a package structure P1 may include a first electrical component 610 and a second electrical component 620 bonded to a bottom electrical component 630 through a plurality of connectors 650. The package structure P1 further includes an underfill layer 640, an encapsulant 645, and a plurality of external connectors 660. Specifically, the underfill layer 640 may laterally encapsulate the connectors 650 and further fill in the gap between the first electrical component 610 and the second electrical component 620. The encapsulant 645 may laterally surround the underfill layer 640, and sidewalls of the first electrical component 610 and the second electrical component 620. The external connectors 660 may be distributed on the lower surface of the bottom electrical component 630 to be electrically and/or physically connected to the circuit substrate (not shown).

In some embodiments, the first electrical component 610 and the second electrical component 620 each has a single function (e.g., a logic device, memory die, etc.), or may have multiple functions (e.g., a SoC). In a particular embodiment, the first electrical component 610 is a logic die and the second electrical component 620 is a memory die. In some embodiments, the first electrical component 610 is a processor, such as a central processing unit (CPU), graphics processing unit (GPU), application-specific integrated circuit (ASIC), or the like. In a specific embodiment, the first electrical component 610 is a system-on-chip (SoC). In some embodiments, the second electrical component 620 is a memory die, such as dynamic random access memory (DRAM) die, static random access memory (SRAM) die, hybrid memory cube (HMC) module, high bandwidth memory (HBM) module, or the like. In a specific embodiment, the second electrical component 620 is the HBM module. In some embodiments, the bottom electrical component 630 is an interposer, such as silicon interposer (e.g., Si wafer).

In some embodiments, one of the connectors 650 is similar to the connector 150 with the UBM structure 110 of FIG. 2, that is, the structures, materials, and functions of the connector 150 is similar to that of the connector 650, and thus the details are omitted herein. In a particular embodiment, the connectors 650 are micro bumps including a solder sandwiched between the UBM structure and the metal pillar or two UBM structures. By using the connector 650 connecting the first electrical component 610 and the bottom electrical component 630 or the second electrical component 620 and the bottom electrical component 630, an adhesion between the UBM structure of the connector 650 and the underfill layer 640 can be effectively improved and further avoid the delamination issue of the underfill layer 640, thereby enhancing the reliability of the package structure P1 with the connectors 650. Although the UBM structure 110 illustrated in FIG. 2 is connected to the upper component (e.g., 610) and the smaller third metal layer 122 faces down, the embodiments of the present invention are not limited thereto. In some alternative embodiments, the UBM structure 110 may be connected to the lower component (e.g., 630) and the smaller third metal layer 122 faces up. In some other embodiments, the UBM structure 110 may be connected to another component (e.g., 620) and the smaller third metal layer 122 faces down.

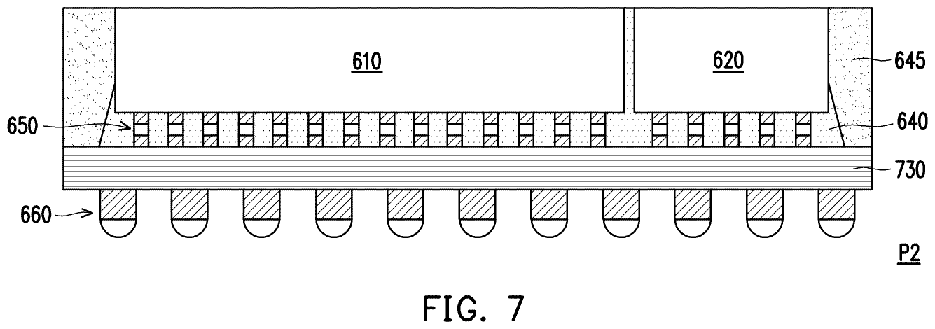

Referring to FIG. 7, a package structure P2 of FIG. 7 is similar to the package structure P1 of FIG. 6, but the bottom electrical component 630 of the package structure P1 is replaced by a redistribution layer (RDL) structure 730 to form the package structure P2. In some embodiments, the RDL structure 730 includes a plurality of polymer layers and a plurality of redistribution layers stacked alternately. The redistribution layers may be formed in the polymer layers to electrically connect the first electrical component 610 and the second electrical component 620. The redistribution layers respectively include a plurality of vias and a plurality of traces connected to each other.

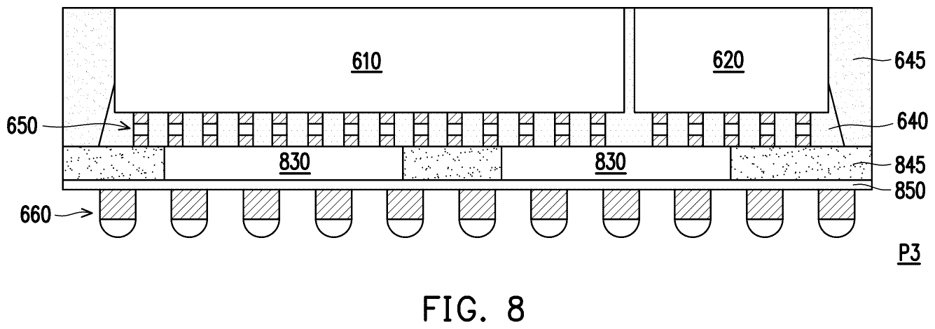

Referring to FIG. 8, a package structure P3 of FIG. 8 is similar to the package structure P1 of FIG. 6, but the bottom electrical component 630 of the package structure P1 is replaced by one or more bridge dies 830 (sometimes referred to as a local silicon interconnect (LSI)) to form the package structure P3. In some embodiments, the bridge dies 830 are used to electrically connect the first electrical component 610 and the second electrical component 620. The first electrical component 610 and the second electrical component 620 may be electrically connected to the external component (e.g., circuit substrate) through the connectors 650, the bridge dies 830, the RDL structure 850, and the external connectors 660. In addition, the package structure P3 further includes another encapsulant 845 laterally surrounding the bridge dies 830.

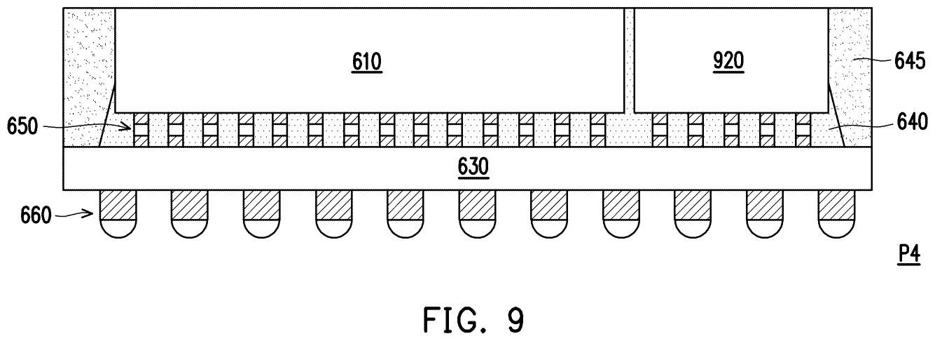

Referring to FIG. 9, a package structure P4 of FIG. 9 is similar to the package structure P1 of FIG. 6, but the second electrical component 620 of the package structure P1 is replaced by a System-on-Integrate-Chips (SoIC) component 920 to form the package structure P4. In some embodiments, the SoIC component 920 include multiple hybrid bonded and stacked semiconductor dies, wherein the semiconductor dies may be different functions and sizes. In some alternative embodiments, the first electrical component 610 may be replaced by a SoIC component.

Moreover, although the said embodiments illustrate four packaging structures with the connectors 650, the embodiments of the present invention are not limited thereto. In other embodiments, the connectors 650 or 150 may be applied to any suitable package structure, such as PoP package structure, InFO package structure, or the like.

According to some embodiments, a structure includes a substrate, an under bump metallurgy (UBM) structure, and a solder. The UBM structure is disposed over the substrate. The UBM structure includes a first metal layer; a second metal layer disposed on the first metal layer; and a third metal layer disposed on the second metal layer. A sidewall of the first metal layer is substantially aligned with a sidewall of the second metal layer, and a sidewall of the third metal layer is laterally offset inwardly from the sidewalls of the first and second metal layers. The solder is disposed on the third metal layer.

According to some embodiments, a method includes forming a first mask layer with a first opening over a substrate; forming a first metal layer and a second metal layer in the first opening; after removing the first mask layer, forming a second mask layer with a second opening over the substrate, wherein a width of the second opening is less than a width of the first opening; and forming a third metal layer and a solder in the second opening.

According to some embodiments, a structure includes a first electrical component bonding to a second electrical component through a plurality of connectors, wherein one of the plurality of connectors comprises: an under bump metallurgy (UBM) structure connecting the first electrical component; a metal pillar connecting the second electrical component; and a solder sandwiched between the UBM structure and the metal pillar, wherein a first width of the solder adjacent to the UBM structure is less than a second width of the solder adjacent to the metal pillar; and an underfill layer laterally encapsulating the plurality of connectors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate;
an under bump metallurgy (UBM) structure, disposed over the substrate, wherein the UBM structure comprises:
a first metal layer;
a second metal layer disposed on the first metal layer; and
a third metal layer disposed on the second metal layer, wherein a sidewall of the first metal layer is substantially aligned with a sidewall of the second metal layer, and a sidewall of the third metal layer is laterally offset inwardly from the sidewalls of the first and second metal layers; and
a solder, disposed on the third metal layer.

2. The structure of claim 1, wherein the third metal layer has a perimeter within a perimeter of the second metal layer in a top view.

3. The structure of claim 1, wherein a non-zero distance is included between the sidewall of the third metal layer and the sidewall of the second metal layer.

4. The structure of claim 1, wherein a material of the second metal layer is different from a material of the first metal layer and/or the third metal layer.

5. The structure of claim 1, wherein the solder is in contact with a surface of the third metal layer without extending to cover the sidewall of the second metal layer.

6. The structure of claim 1, further comprising: a blocking structure disposed on the second metal layer and laterally surrounding the third metal layer.

7. The structure of claim 6, wherein the blocking structure is a ring structure with at least one opening, and the blocking structure and the third metal layer are at the same level.

8. The structure of claim 6, wherein a recess is included between the blocking layer and the third metal layer to accommodate a portion of the solder.

9. The structure of claim 6, wherein the blocking structure and the third metal layer have the same material.

10. The structure of claim 6, wherein the blocking structure and the second metal layer have the same material.

11. A method, comprising:
forming a first mask layer with a first opening over a substrate;
forming a first metal layer and a second metal layer in the first opening;
after removing the first mask layer, forming a second mask layer with a second opening over the substrate, wherein a width of the second opening is less than a width of the first opening; and
forming a third metal layer and a solder in the second opening.

12. The method of claim 11, wherein a sidewall of the first metal layer is substantially aligned with a sidewall of the second metal layer, and a sidewall of the third metal layer is laterally offset inwardly from the sidewalls of the first and second metal layers.

13. The method of claim 11, wherein the second mask layer extends along a sidewall of the first metal layer and a sidewall of the second metal layer and covers a portion of a top surface of the second metal layer.

14. The method of claim 11, wherein the third metal layer has a perimeter within a perimeter of the second metal layer.

15. The method of claim 11, wherein a material of the second metal layer is different from a material of the first metal layer and/or the third metal layer.

16. The method of claim 11, further comprising:
removing the second mask layer; and
performing a reflow process, so that the solder forms a solder bump, wherein the solder bump is in contact with a surface of the third metal layer without extending to cover a sidewall of the second metal layer.

17. A structure, comprising:
a first electrical component bonding to a second electrical component through a plurality of connectors, wherein one of the plurality of connectors comprises:
an under bump metallurgy (UBM) structure connecting the first electrical component;
a metal pillar connecting the second electrical component; and
a solder sandwiched between the UBM structure and the metal pillar, wherein a first width of the solder adjacent to the UBM structure is less than a second width of the solder adjacent to the metal pillar; and
an underfill layer laterally encapsulating the plurality of connectors.

18. The structure of claim 17, wherein the UBM structure comprises:
a first metal layer adjacent to the first electrical component;
a second metal layer disposed on the first metal layer; and
a third metal layer disposed on the second metal layer, wherein a sidewall of the first metal layer is substantially aligned with a sidewall of the second metal layer, and a sidewall of the third metal layer is laterally offset inwardly from the sidewalls of the first and second metal layers.

19. The structure of claim 18, wherein the third metal layer has a perimeter within a perimeter of the second metal layer.

20. The structure of claim 18, further comprising: a blocking structure disposed on the second metal layer and laterally surrounding the third metal layer.
